(19) United States
(12) Patent Application Publication
(10) Pub. No.: US 2010/0227094 A1
(43) Pub. Date: Sep. 9, 2010

(54) OXYGEN BARRIER MOLDED CONTAINER AND METHOD FOR PRODUCTION THEREOF

(75) Inventors: Rodrick Levesque, Levis (CA); Michel Fillion, Beaumont (CA); Stephane Mercier, St-Damien (CA)

Correspondence Address: EDWARDS ANGELL PALMER & DODGE LLP, P.O. BOX 55874, BOSTON, MA, 02205, US

(73) Assignee: IPL, Inc., St-Damien (CA)

(21) Appl. No.: 12/717,678

(22) Filed: Mar. 4, 2010

Related U.S. Application Data
(60) Provisional application No. 61/158,604, filed on Mar. 9, 2009.
(60) Provisional application No. 61/230,328, filed on Jul. 31, 2009.

(51) Int. Cl. B32B 1/02; B29C 45/14; B05D 1/02; B05D 1/18; C23C 16/44; B05D 3/02; B05D 7/22; B32B 27/30; B29D 22/00; B32B 27/08

(52) U.S. Cl. 428/36.7; 264/275; 427/421.1; 427/430.1; 427/248.1; 427/314; 427/236; 427/237; 427/230; 264/134; 428/34.1

(57) ABSTRACT

A method for manufacturing of a plastic container which is substantially impervious to oxygen by providing a bottom film oxygen barrier, the film oxygen barrier having an area greater than the area of a floor of the plastic container; providing a side oxygen barrier film, the side oxygen barrier film being dimensioned to circumscribe a sidewall of the plastic container and having a length greater than the length of the plastic container. A mold has a floor and a sidewall, the mold having a groove extending below the floor and dimensioned to receive an excess length of the side oxygen barrier film therein, and the bottom oxygen barrier film being dimensioned to extend at least partially across said groove. The film oxygen barriers are placed within the mold and a plastic container is injection molded within the cavity.

An oxygen resistant container has a floor. A sidewall extends from the floor. An oxygen barrier material is disposed on the floor and sidewall. The oxygen barrier material is one of a nano-silicate and a nano-clay.

### CROSS-REFERENCE TO RELATED APPLICATIONS

This application claims the benefit of priority to U.S. Provisional Application No. 61/158,604, filed Mar. 9, 2009 and U.S. Provisional Application No. 61/230,328, filed Jul. 31, 2009 in their entirety.

### BACKGROUND OF THE INVENTION

This invention is related to molded plastic containers, and in particular, creating a molded plastic container which also acts as an oxygen barrier to products contained therein.

It is well known in the art that plastic pails and containers are used for the storing of perishable items. The shelf life of perishable items such as foods, medicines and paints are affected by temperature, humidity and most importantly oxidation. In order to improve shelf life, many approaches have been taken including the formation of airtight seals, the use of better plastic materials, the use of plastic and foil seals across the opening of the container below the cap or lid of containers and even the use of labels about the container to prevent or slow down the rate at which the perishable item is exposed to oxygen. These prior art structures have been satisfactory, however, the plastic materials used for molding of containers still allow oxygen to pass there through and conventional labels do not envelope enough of the container surface to form an effective barrier. Therefore, over time, oxygen passes through the walls of injection, thermoformed and blow molded containers.

Accordingly, a structure and methodology for creating the containers which increases the impermeability of a molded plastic container wall, floor or lid to oxygen is desired.

### BRIEF SUMMARY OF THE INVENTION

A container is molded from a plastic. A film is coated or formed or included with an oxygen barrier solution and then applied to the molded container. The film may be formed of a multilayer structure including a deposit of nano-particles sprayed on a film substrate. The film is applied to the container during an injection molding of the container by an injection mold label process. In a preferred embodiment, the nano-particles are silicate based.

During the molding process, a film is used to cover the container. A bottom film and a sidewall film may be utilized. The bottom film has an area greater than the area of a bottom of the container while the sidewall film substantially circumscribes the sidewall container and has a length greater than the length of the sidewall of the container. The bottom film and sidewall film are affixed to a mandrel. The mandrel is inserted into the injection mold cavity and each film separates from the mandrel into the cavity. The cavity may be formed with a groove therein adjacent a floor of the cavity. A region of the bottom film which extends beyond the area of the bottom of the container extends across the groove, and the portion of the sidewall film which extends beyond the container sidewall is received within the groove. A plastic shot is then injection molded into the cavity filling the groove during the molding process.

In another embodiment, no film is utilized and the container is formed with an oxygen barrier solution applied to the stock plastic material. The oxygen barrier is a nano-solution. In any embodiment, the plastic material may be pretreated through a heat treating process prior to application of the nano-particles.

### BRIEF DESCRIPTIONS OF THE DRAWINGS

FIG. 1 is a perspective partial exploded view of a container formed in accordance with the invention;

FIG. 2 is a sectional view of the label constructed in accordance with the invention;

FIG. 3 is a schematic diagram of a first step in the process for injection molding an oxygen barrier about a container in accordance with the invention;

FIG. 4A is a sectional view of an exemplary mold utilized for the application of an oxygen barrier to the container in accordance with the invention;

FIG. 4B is an enlarged view of the groove area of FIG. 4;

FIGS. 5A, 5B are before and after schematic diagrams showing the behavior of the bottom oxygen barrier film during the molding process in accordance with the invention; and

FIG. 6 is a partial sectional view of a container formed utilizing the mold of FIG. 4 in accordance with the invention.

### DETAILED DESCRIPTION OF THE INVENTION

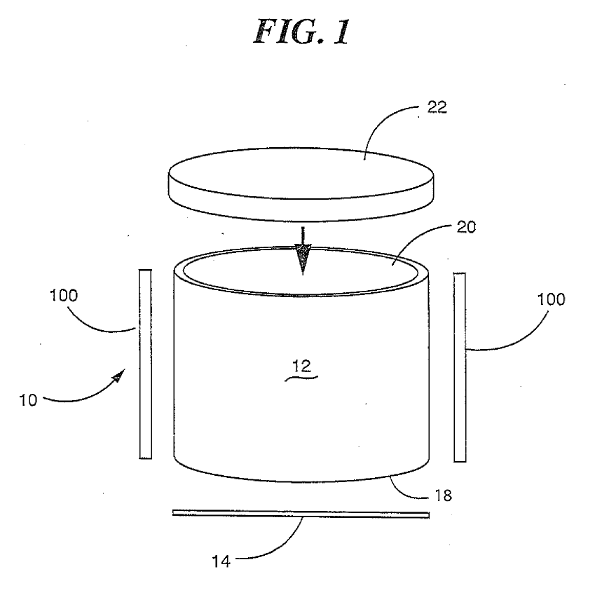

As is known in the art, and is shown in FIG. 1, a container 10 constructed in accordance with the invention has enclosing side wall 12 and a floor 18 to provide a container having one open end 20. A lid 22 is fitted across open end 22 to close the container sealing contents therein.

During manufacture to create container 10, a shot of plastic, such as polypropylene material by way of non-limiting example, is injection molded to form container 10, and/or lid 22.

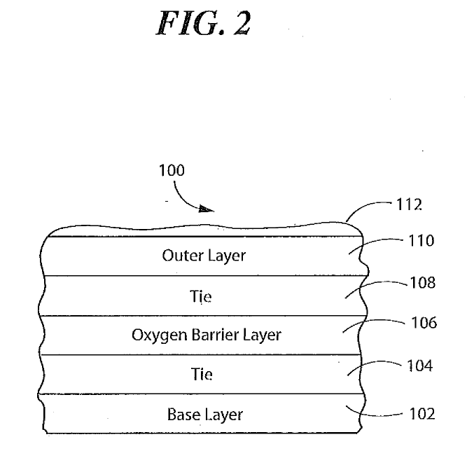

Apart from the manufacture of the container itself, a thin film barrier 100 is manufactured. The label may be a multilayer structure. In a preferred embodiment, thin film 100 is applied as an in mold label. In a preferred example, as shown in FIG. 2, thin film 100 includes a first layer 102 which serves as a base layer. A tie layer 104 is disposed between first layer 102 and a gas barrier layer 106. A second tie layer 108 is disposed between the gas barrier layer 106 and an outer layer 110. At least one layer of the film is coated with, formed with, or includes within its structure an oxygen barrier solution to form oxygen barrier layer 112.

Thin film barrier 100 is applied to sidewall 12. A bottom film 14, having a similar structure to film 100 is applied to bottom 18.

In a preferred embodiment, the barrier solution is formed from a nano-silicate solution or a nano-clay formed as an aqueous suspension as known from NanoLok PT MM manufactured by InMat Inc. A porous cylinder is used to dispose the aqueous nano-solution across at least one of first layer 102 or outer layer 110 of the film 100 by way of nonlimiting example. The barrier solution may also be disposed between layer 102 and 110 and an internally adjacent layer. The thickness of the nanosolution layer 112 is controlled by the diameter of the pores within the cylinder and the internal pressure of the cylinder. Other application methods such as cascade coating may be used. In a preferred embodiment, the thickness of the aqueous solution layer 112 is less than or equal to 3 microns.

In a preferred, nonlimiting example, the first layer 102 and outer layer 110 are formed as plastic films, and more preferably polypropylene. However, first layer 102 may be formed of treated or untreated paper, foil or the like.

The gas barrier layer 106 (preferably an oxygen barrier layer) may be formed from an EVOH. Layer 106 of thin film 100 could be replaced or coupled with PVDC (polyvinylidene chloride), aluminum, PVOH (polyvinyl alcohol), aluminum oxide, silicium oxide, a nanoclay or nanocrystalline cellulose alone or in any combination thereof. The properties of the various layers may enable film 100 to act as a moisture and/or light barrier. Furthermore, when thin film 100 is applied to an outer surface of container 10 such as sidewall 12 and bottom 18 as film 14, in sections 202, 204, thin film 100 may be printed upon with ink to form a label without affecting the use of the barrier's nano-particle layer 112. The film may also be provided on the interior structure of container 10 such as the interior of sidewall 12, floor 18 or lid 22.

In order to maximize the oxygen barrier nature of the present invention, it is preferred to encapsulate, i.e. substantially entirely cover the container with the barrier with any of the films discussed above so that a film covering at the bottom and about the sidewall of the container is desired. However, prior art molding processes resulted in the interference between the bottom film and the side film in the injection mold label formation process.

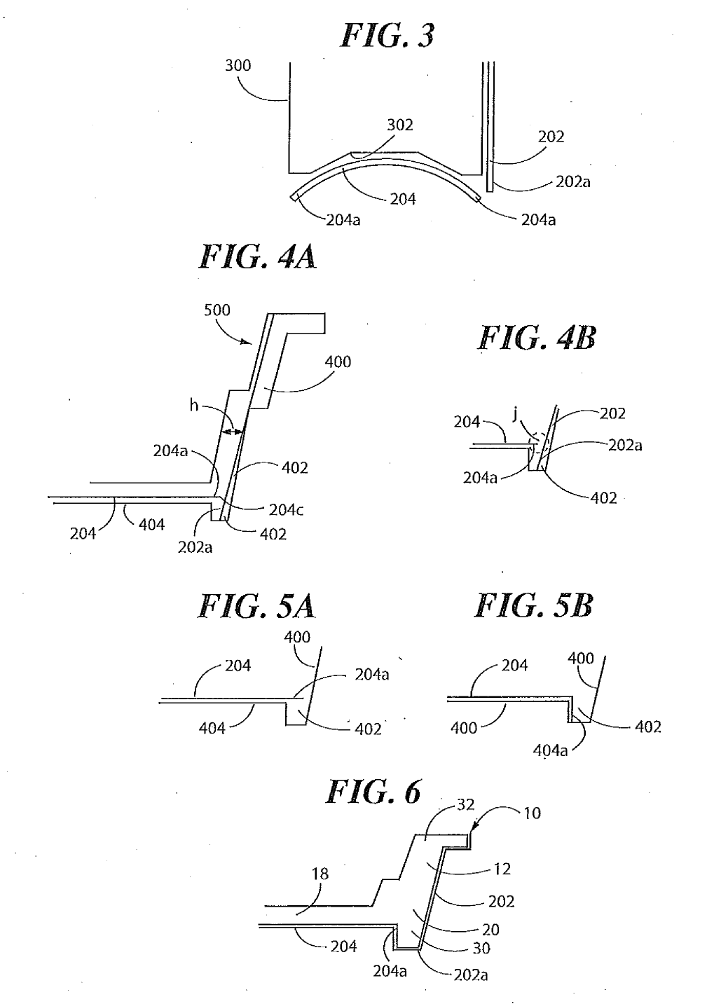

In accordance with a preferred embodiment of the present invention, a bottom film 204 and a sidewall film 202 are carried by a formed mandrel 300 as shown in FIG. 3. Mandrel 300 includes a concave bottom portion 302. Bottom film 204 has an area greater than the bottom surface of bottom portion 302. Side film 202, which is a wrap around film (in that it substantially wraps around the entire circumference of mandrel 300), has a length greater than mandrel 300.

Bottom film 204 also has an area greater than an area of container bottom 10. Side film 202 has a length greater than a length of sidewall 12. In this way, bottom film 204 extends beyond the bottom 18 of container 10 by an overhang portion 204a. Similarly, side film 202 overhangs container wall 12 by an overhang portion 202a. In order to prevent interference between bottom film 204 and wrap around film 202 during the molding process, a bottom surface 302 of mandrel 300 is formed at least in part with a concave shape to arc bottom film 204 to take up any slack and prevent interference between wrap around film 202 and bottom film 204. Each of wrap around film 202 and bottom film 204 are held to mandrel 300 by a vacuum pressure at mandrel 300 and/or a static charge of between 10 and 12 K volts.

In a next step, mandrel 300 with films 202, 204 thereon are inserted into a mold steel cavity 400 (see FIG. 4A). Mold steel cavity 400 is formed with a groove 402 which extends below a floor 404 of mold steel cavity 400 much like the heel of a boot. Groove 402 receives the excess length of respective overhangs 202a, 204a of both label 202 and label 204 therein.

As seen in FIG. 4A, a molded steel core 500 is inserted within mold steel cavity 400 with a gap h between the two as known in the art, to provide space for receiving the plastic shot during the molding process. The width of gap h being a function of the thickness of the desired, container.

As seen in FIG. 4B, a gap j exists between an edge 204c of bottom film 204 and a planer surface of side label 202. The gap is a function of the minimum distance required to separate a bottom label 204 having a section 204a sufficiently sized to cover an inner surface of the foot 30 (extend sufficiently across groove 402) without contacting side label 202. In a preferred embodiment, gap j is about 0.005 inches. It should be noted that side label 202 is sufficiently longer than a side wall of container 10 so as to have sufficient material to cover the bottom and outside surface of foot 30, all of the sidewall of container 10 and, in a preferred nonlimiting example, any overhanging lip 32 (see FIG. 6).

In another embodiment, a single film diper label may be used. A five faced diper label positioned at the bottom of mold 400 and used in an injection mold process would still cover 99.1% of the outer container surface. However, the preferred embodiment is the two label method which covers more than 99.4% of the surface.

Because of the level of static charge, air flow from the mandrel forces the label to the mold and the fact that the mold is made out of steel, when mandrel 300 is inserted into mold cavity 400, the attraction as a result of the static charge plus the air flow, between either of label 202, 204 and mold cavity 400 is greater than the attraction between either of film 202, 204 and mandrel 300. Accordingly, once in sufficient proximity to mold cavity 400, the labels 202, 204 are released from mandrel 300 and are held in place by the respective wall 402 and floor 404 of cavity 400.

As seen in FIGS. 5A, 5B, film 204 is sufficiently rigid to maintain its shape across groove 402 (FIG. 5A). However, during the injection molding process, the plastic shot, as it takes form, moves into groove 402 and forces overhang 204a of bottom film 204 into groove 402 and in fact, pinned against a wall 402 by the plastic as it attaches to the plastic. Similarly, the shot pushes overhang 202a of film 202 against a floor 404 of groove 402 between the shot and the floor.

As can be seen from FIG. 6 in which a container molded from cavity 400 and core 500 is provided, because bottom label 204 has an area greater than the area of container bottom 18 including an overhang 204a sufficient to cover an inside surface of foot 30 of container 10, and side label 202 encircles sidewall 12 of container 10 and has a length greater than sidewall 12 sufficient to extend at least partially into groove 402 and cover a bottom and side of foot 30, and labels 202 and 204 are close proximity at overhangs 204A, 202A, the encapsulation of plastic container 10 is optimized. Also label 202 extends at the top of the container (the lip) to optimize covering lip 32.

It is understood that films 202, 204 may have the structure of film 100. In another embodiment of the invention, a barrier solution is formed in a liquid or gel state. In a preferred embodiment, the solution is a nano-clay formed of an aqueous suspension of nano-dispersed silicate and polyester resin such as NanoLok PT MM manufactured by InMat Inc, The barrier may also be a resin which cures about the container.

The aqueous gel may be applied as discussed above in connection with film 100 to an inner or outer surface of any of sidewall 12 or floor 18 by way of a dipping process, vapor deposition, an aqueous spray, or a fine particulate atomized spray. In a preferred embodiment, container 10 may be heat treated prior to the deposition of the aqueous barrier solution onto a surface of container 10.

Lid 22 may be treated in the same way as the body of the container to enhance the oxygen barrier properties of lid 22.

In an alternative embodiment, the polypropylene stock material may be treated with the aqueous barrier solution prior to injection molding to form container 10. The raw stock of material such as polypropylene material may be dipped in a liquid or gel state of the barrier material, sprayed with the barrier material, or subject to vapor deposition of the barrier material or an atomized version of the solution. In this way, the injection molded lid 22 and/or container 10 are formed with an inherent oxygen barrier.

While this invention has been particularly shown and described with reference to the preferred embodiments thereof, it will be understood by those skilled in the art that various changes in form and detail may be made therein without departing from the spirit and scope of the encompassed by the appended claims.

What is claimed is:

1. A method for manufacturing of a plastic container which is substantially impervious to oxygen comprising the steps of:
providing a bottom film oxygen baffler, the bottom film oxygen barrier having an area greater than the area of a floor of the plastic container;
providing a side oxygen barrier film, the side oxygen barrier film being dimensioned to substantially circumscribe a sidewall of the plastic container and having a length greater than the length of the sidewall of the plastic container;
providing a mold, the mold having a floor and a sidewall, the mold having a groove extending below the floor and dimensioned to receive an excess length of the side oxygen barrier film therein;
placing the bottom oxygen barrier film and side oxygen barrier film in the mold, the bottom oxygen barrier film being dimensioned to extend at least partially across said groove and a portion of the side barrier film extending into the groove; and
injection molding a plastic container within the cavity.

2. The method for manufacturing of a plastic container of claim 1, further comprising providing a mandrel, applying said side oxygen barrier film about the mandrel, the sidewall oxygen barrier film having a length greater than the length of the mandrel, and said mandrel, the bottom label having an area greater than the area of a bottom surface of the mandrel;
simultaneously carrying the bottom oxygen barrier film and said side oxygen barrier film with the mandrel; and
depositing the bottom oxygen barrier film and the side oxygen barrier film within the mold utilizing the mandrel.

3. The method of claim 2, further comprising the step of forming a bottom surface of the mandrel as a concave surface.

4. The method for manufacturing of claim 2, further comprising the steps of applying the side oxygen barrier film and the bottom oxygen barrier film to the mandrel with a static electric charge.

5. The method for manufacturing of claim 1, further comprising forming at least one of the side oxygen barrier film and the bottom oxygen barrier film by forming an aqueous solution of an oxygen barrier material and applying the aqueous solution to a surface of the film.

6. The method of claim 5, wherein the oxygen barrier material is formed of nano-dispersed silicate.

7. The method of claim 5, wherein the oxygen barrier material is a nano-clay.

8. The method of claim 6, wherein the aqueous solution is applied to the film by spraying a layer of oxygen barrier material on at least one side of the film.

9. A method for manufacturing of a plastic container which is substantially impervious to oxygen comprising the steps of:
forming an oxygen barrier aqueous gel;
forming a plastic container by injection molding; and
applying the aqueous gel by one of a dipping process, vapor deposition, an aqueous spray, and a fine particulate atomized spray.

10. The method for manufacturing of a plastic container of claim 9, further comprising the step of heat treating the plastic container prior to the deposition of the aqueous barrier solution.

11. The method of claim 9, wherein the aqueous gel is applied to at least one of an inner surface or an outer surface of a side wall and a floor of the plastic container.

12. The method of manufacture of claim 9, wherein said aqueous oxygen barrier gel is a nano-clay formed as an aqueous suspension.

13. A method for manufacturing of a plastic container which is substantially impervious to oxygen comprising the steps of:
treating a raw stock polypropylene material with an aqueous oxygen barrier solution;
and injection molding the polypropylene material to form a container.

14. The method of manufacture of claim 13, in which the raw stock material polypropylene is treated with the oxygen barrier material by at least one of dipping in a liquid or gel state of the oxygen barrier material, being sprayed with the oxygen barrier material, being made subject to vapor deposition of the oxygen barrier material or being sprayed with an atomized version of an oxygen barrier solution.

15. The method of manufacture of claim 14, wherein the aqueous oxygen barrier solution is an aqueous suspension of a nano-dispursed silicate and polyester resin.

16. An oxygen resistant container comprising:
a floor, a sidewall extending from said floor;
an oxygen barrier material being disposed on said floor and sidewall; and
the oxygen barrier material being one of a nano-silicate and a nano-clay.

17. The container of claim 16, further comprising a film disposed on a surface of the floor, the film having at least one surface coated with the oxygen barrier.

18. An oxygen resistant container comprising:
a floor, a sidewall extending from said sidewall;
an oxygen barrier material being disposed on said sidewall; and
the oxygen barrier material being one of a nano-silicate and a nano-clay.

19. The container of claim 18, further comprising a film being disposed about said sidewall, the oxygen barrier material being disposed on the film, and wherein the film is a multilayer structure having a first layer, a polyvinylidene chloride layer, a tie layer disposed between the first layer and the polyvinylidene chloride layer, and an outer layer, a second tie layer disposed between said polyvinylidene chloride layer and the outer polypropylene layer.

20. The container of claim 19, wherein at least one of the first layer and outer layer are formed of a plastic film.
